(19) United States
(12) Patent Application Publication
(10) Pub. No.: US 2003/0075774 A1
(43) Pub. Date: Apr. 24, 2003

(54) Bipolar transistor

(76) Inventor: Byung Ryul Ryum, Taejon (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 10/271,547

(22) Filed: Oct. 17, 2002

(30) Foreign Application Priority Data
Oct. 22, 2001 (KR) 2001-65209

(51) Int. Cl. H01L 29/00

(52) U.S. Cl. 257/511

(57) ABSTRACT

Disclosed is a bipolar transistor capable of reducing an emitter area at a given operating frequency and output power, as well as satisfying a demand for a device having a higher output power and operating frequency. The bipolar transistor includes a bar-type trunk having a polygonal cross-section, and a plurality of polygonal branches having a polygonal cross-section connected to the trunk, in which a current operating performance of the emitter is improved by increasing a value of a planar structure of the emitter.

### BACKGROUND OF THE INVENTION

1. Field of the Invention

The present invention relates to a bipolar transistor, and more particularly, to a bipolar transistor capable of increasing an operating frequency and simultaneously increasing an output power.

2. Background of the Prior Art

FIG. 1 is a top plan view of a conventional bipolar transistor, in which an emitter 1-1, a base 1-2 and a collector 1-3 are connected to an emitter metal electrode contacted window 1-4, a base metal electrode contacted window 1-5 and a collector metal electrode contacted window 1-6, respectively.

Due to inherent characteristics of the bipolar transistor, an area of the emitter 1-1 has to be enlarged to increase an amount of current vertically flowing to the collector, and a breakdown voltage between the collector 1-3 and the emitter 1-1 has to be increased to raise the bias voltage between the collector and the emitter.

If the breakdown voltage (BV_{CEO}) between the collector 1-3 and the emitter 1-1 is increased, a cutoff frequency (f_{T}) of the device is adversely decreased (BV_{CEO}×f_{T}=a constant). Moreover, the maximum oscillation frequency (fₘₐₓ) of the device is decreased due to the relationship of (f_{T}/(8πR_{B}×C_{JC}))^{1/2}, thereby reducing the power amplification gain and thus deteriorating the performance of the device, in which R_{B} is a resistance of the base, and C_{JC} is a capacitance between the collector and the base.

In order to enlarge the emitter area for increasing the output collector current, the emitter width (W) perpendicular to the emitter length (L) has to be enlarged. Due to the voltage drop laterally produced in the base along a horizontal path of a base current until the base current arrives at the emitter at a high level of the base current in accordance to the increased collector current, an emitter crowding effect remarkably appears, so that the collector current crowds along the edge of the emitter when viewing at the cross-section of the emitter. Even though the emitter width is enlarged, the current may not flow in the level corresponding to the enlarged width, but only the emitter area is enlarged. In addition, since C_{JC} is unnecessarily increased, the maximum oscillation frequency (fₘₐₓ) of the device is lowered.

Therefore, there is a limit to the enlargement of the emitter width for increasing the collector current and thus output power thereof.

### SUMMARY OF THE INVENTION

Accordingly, the present invention is directed to a bipolar transistor that substantially obviates one or more problems due to limitations and disadvantages of the related art.

It is an object of the present invention to provide a bipolar transistor capable of reducing an emitter area at a given operating frequency and output power, as well as satisfying a demand for a device having a higher output power and operating frequency.

In order to accomplish the above objects, the present invention provides a bipolar transistor including an emitter, a base and a collector, the bipolar transistor comprising: a bar-type trunk having a polygonal cross-section; and a plurality of polygonal branches having a polygonal cross-section connected to the trunk, in which a current driving performance of the emitter is improved by increasing a value perimeter/area of the emitter.

According to the bipolar device, an emitter area (A_{E}) of the device has to be enlarged to increase the output current thereof and thus the output. To this end, an emitter width (W) perpendicular to a given emitter length (L) has to be enlarged. At that time, due to the voltage drop laterally produced in the base by the resistance of a base layer along a horizontal path of a base current until the base current arrives at the emitter at a high level of the base current in accordance to the increased collector current, the base-emitter voltage V_{BE} applied to an edge is higher when viewing at the cross-section of the emitter, while the V_{BE} is gradually decreased by the lateral voltage drop toward an emitter center, so that a collector current (I_{C}) determined by exp(V_{BE}/V_{T}) is higher along the emitter edge to appear an emitter crowding effect, in which V_{T} means a thermal voltage. Therefore, even though the emitter width is enlarged, the current may not flow in the level corresponding to the enlarged width. On the contrary, the A_{E} is enlarged. In addition, since a capacitance (C_{JC}) is unnecessarily increased, the maximum oscillation frequency (fₘₐₓ) of the device is lowered.

Accordingly, the longer the emitter perimeter, the higher the collector current flows when the emitter crowding effect appears. In other words, the larger a value of the emitter perimeter/emitter area, i.e., P_{E}/A_{E}, the higher output power the device has.

It is to be understood that both the foregoing general description and the following detailed description of the present invention are exemplary and explanatory and are intended to provide further explanation of the present invention as claimed.

### BRIEF DESCRIPTION OF THE DRAWINGS

The accompanying drawings, which are included to provide a further understanding of the present invention and are incorporated in and constitute a part of this application, illustrate embodiment(s) of the present invention and together with the description serve to explain the principle of the present invention. In the drawings:

FIG. 1 is a top plan view of a conventional bipolar transistor;

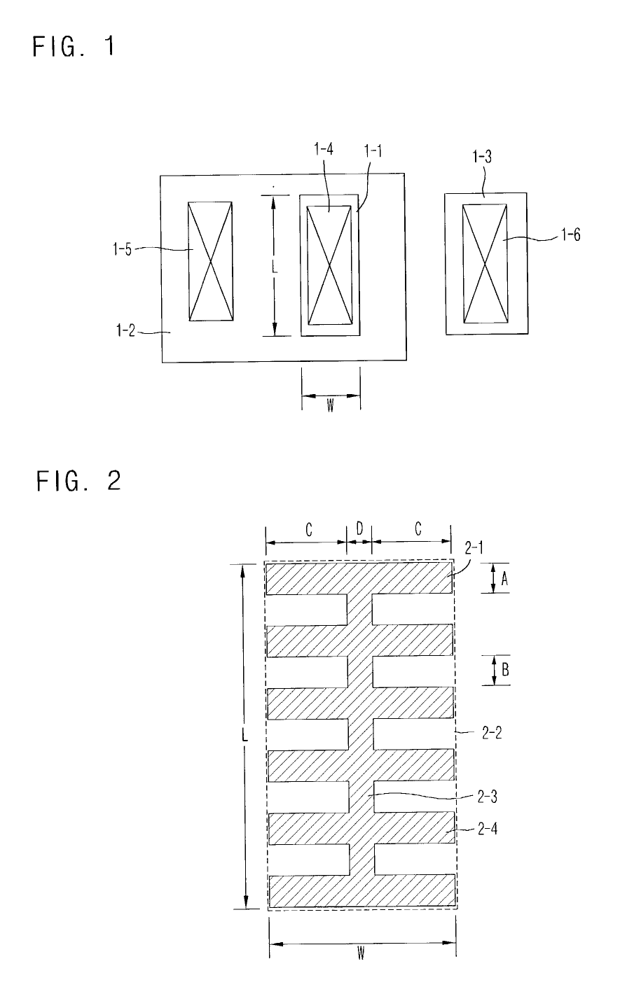

FIG. 2 is a top plan view of a bipolar transistor according to one preferred embodiment of the present invention; and

FIG. 3 is a top plan view of an emitter of a bipolar transistor according to one preferred embodiment of the present invention.

### DETAILED DESCRIPTION OF THE PREFERRED EMBODIMENTS

Reference will now be made in detail to a preferred embodiment of the present invention.

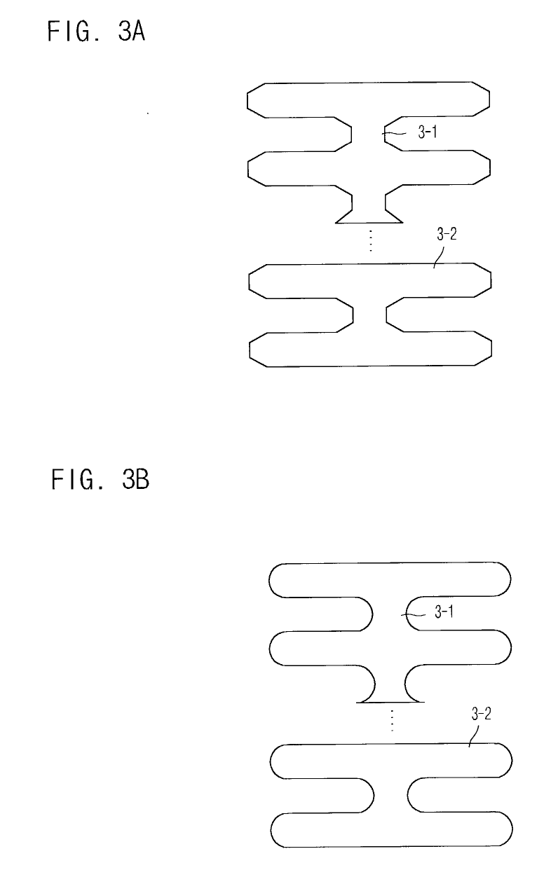

FIG. 2 is a top plan view of a bipolar transistor according to one preferred embodiment of the present invention.

As shown in FIG. 2, a top view 2-1 of an emitter according to the present invention includes a bar-type trunk 2-3 having a polygonal cross-section and a plurality of polygonal branches 2-4 connected to the trunk 2-3.

For example, in case of a tetragonal trunk having a plurality of tetragonal branches, if each of A, B and C is 2 μm and C is 4 μm, W is 10 μm and L is 22 μm.

The planar area (W×L) of the planar structure of the conventional emitter is 220 μm², and the emitter perimeter (2(W+L)) is 64 μm, so that the value of P_{E}/A_{E} is 0.3 μm. Meanwhile, according to the present invention, the emitter perimeter ((2A×6)+(2C×12)+(2B×5)+(2D×2)) is 148 μm, and the emitter area (6×(2C+D)×A+5×B×D) is 140 μm², so that the value of P_{E}/A_{E} is 1.06 μm.

The value of P_{E}/A_{E} of the emitter according to the present invention is increased at least three times more than the planar structure 2-2 of the conventional emitter. In other words, if the value of A_{E} is constant and the value of P_{E} is increased at least three times, the current is increased three times, and thus the output power is also increased three times. Otherwise, if the value of P_{E} is constant and the value of AE is decreased three times, the value of C_{JC} is decreased three times to increase f_{MAX}, and simultaneously, the power amplification gain is increased at the given frequency.

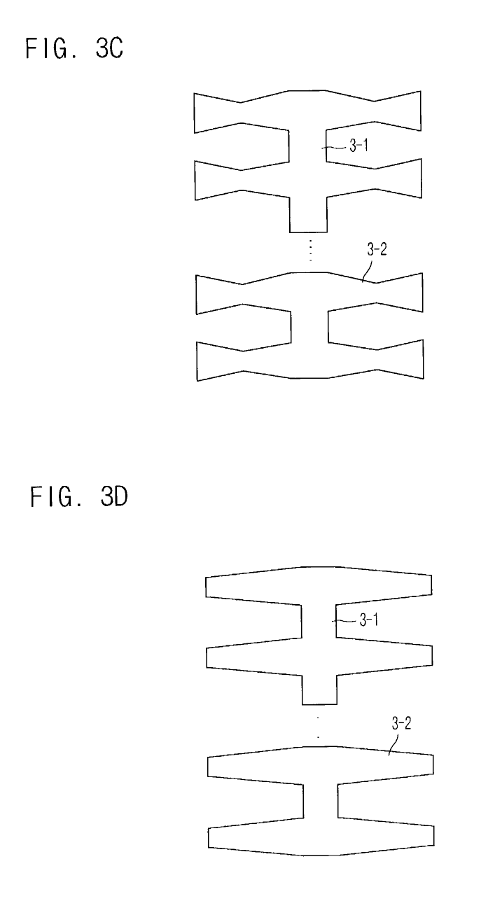

FIG. 3 is a top plan view of the emitter of the bipolar device according to one preferred embodiment of the present invention.

As shown in FIG. 3, the top view of the emitter includes a polygonal trunk 3-1 which is bent more than once, and a plurality of polygonal branches 3-2 each having at least two curved sides.

It is noted that the shape of the trunks 2-3 and 3-1 or branches 2-4 and 3-2 may be changed in various types, and only one among the possible shapes is shown herein.

With the structure described above, the present invention may minimize the reduction of the operating frequency and increase the output power, thereby satisfying the demand for the device having the higher output power and the higher operating frequency in accordance to the gradually increased communication frequency. Meanwhile, the manufacture cost may be decreased by reducing the area of the device at the given operating frequency and output power.

The forgoing embodiment is merely exemplary and is not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A bipolar transistor including an emitter, a base and a collector, the bipolar transistor comprising:
a bar-type trunk having a polygonal cross-section; and
a plurality of polygonal branches having a polygonal cross-section connected to the trunk,
in which a current driving performance of the emitter is improved by increasing a value perimeter/area of a top view of the emitter.

2. The bipolar transistor as claimed in claim 1, wherein the bar-type trunk has a polygonal cross section, of which a portion of the trunk is bent at least once.

3. The bipolar transistor as claimed in claim 1, wherein the branches have at least one curved side.

4. The bipolar transistor as claimed in claim 1, wherein at least one curved side of the branch of polygonal cross-section is recessed.
